(19) United States
(12) Patent Application Publication
(10) Pub. No.: US 2007/0235795 A1
(43) Pub. Date: Oct. 11, 2007

(54) Ferroelectric storage device and manufacturing method thereof

(76) Inventor: Susumu Shuto, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/727,148

(22) Filed: Mar. 23, 2007

(30) Foreign Application Priority Data
Mar. 24, 2006 (JP) P2006-084194

(51) Int. Cl. G11C 11/22; H01L 29/76

(52) U.S. Cl. 257/314; 365/145

(57) ABSTRACT

According to an aspect of the embodiment, there is provided a ferroelectric storage device including: a plurality of memory cells repeatedly arranged in a predetermined direction, each memory cell including a ferroelectric film divided for each memory cell; and a word line formed on the ferroelectric film and shared by the plurality of memory cells.

### CROSS-REFERENCE TO RELATED APPLICATION

This application is based upon and claims the benefit of priority from the prior Japanese Patent Application No. 2006-084194, filed on Mar. 24, 2006; the entire contents of which are incorporated herein by reference.

### TECHNICAL FIELD

The present invention relates to a ferroelectric storage device and a method thereof.

### BACKGROUND

Concerning the structure of a nonvolatile memory cell in which a ferroelectric film is used, the following two types are provided.

(1) 1T1C type (1−transistor +1 capacitor type memorycell) in which a ferroelectric film is used for a capacitor portion of DRAM (Dynamic Random Access Memory) memory cell.

(2) 1T type (1−transistor type memory cell, for example, shown in Patent Document 1), the data storage element of which includes a ferroelectric film used for a gate insulating film of a field effect transistor.

In the case of 1T type, a memory cell includes one field effect transistor. Therefore, as compared with the case of 1T1C type, it is possible to more densely arrange the memory cells in the case of 1T type. 1T type is used for a nonvolatile memory of a large capacity.

In a ferroelectric storage device in which a related-art 1T type memory cell is used, as shown in FIG. 8, such a structure is adopted that the gate electrodes of the memory cells are commonly connected to each other so as to be used as a word line. According to this structure, the memory cells can be densely arranged. As shown in FIG. 8A when viewed from a plan view, on both sides of the word line 102 (gate electrode), active regions 103 (source electrodes and drain electrodes) are arranged on the upper and the lower side, and a plurality of memory cells are repeatedly arranged in the lateral direction on both sides of the element separation region 104. Since the ferroelectric film 106 serving as a gate insulating film is formed together with the word line 102, as shown in FIG. 8B, the ferroelectric film 106 is commonly connected between the memory cells adjacent to each other in the direction of the word line. The ferroelectric film 106 is continuously formed on the element separation region 104 which separates the active regions 103 of the adjoining memory cells 101.

However, in the related-art ferroelectric storage device as described above, the following problems may be encountered. Since the ferroelectric film 106 is continuously formed between the memory cells having the word line 102 in common, the adjoining ferroelectric films interfere with each other. Accordingly, there is a possibility that data stored in the memory cell 101 is rewritten.

For example, in case where data “1” is written in the memory cell 101 and data “0” is written in the two memory cells which are adjacent to each other, on the assumption that data “0” is previously written in the memory cells, the following electric potential is given to each terminal at the time of writing. A ground electric potential (referred to as “GND” hereinafter) is applied to a bit line of the memory cell 101, an electric potential of an electric power source (referred o as “Vcc” hereinafter) is applied to a bit line of the adjoining memory cell, and Vcc is applied to a word line. Due to the foregoing, a polarization of the memory cell 101 is inverted and directed in a direction from the word line to a board. The direction is shown by a downward arrow in FIG. 8B. A polarization of the adjoining memory cell is not inverted. Therefore, the polarization of the adjoining memory cell is left as it is in such a manner that the polarization of the adjoining memory cell is directed in a direction from the board to the word line. This direction is shown by an upward arrow in FIG. 8B. Therefore, in a boundary of the memory cell 101 and the adjoining memory cell, that is, on the element separation region 104, there is some region where the polarization of the ferroelectric film 106 is directed upward and other region wherein the polarization of the ferroelectric film 106 is directed downward. Both regions surrounded by a broken line in FIG. 8B are contacted with each other. In both regions the polarization is unstable. Therefore, an amount of the effective polarization in this case is smaller than that of a case in which the polarization of the memory cell 101 and that of the adjoining memory cell are directed in the same direction. An amount of the polarization stored in the memory cell 101 is changed by the data written in the adjoining memory cell. Depending upon the case, this could be a cause of an erroneous readout of the memory cell 101.

Recently, the technique of manufacturing semiconductors has advanced and semiconductors, the structure of which is fine, have been produced. Therefore, an interval between the adjacent memory cells has been reduced. Accordingly, serious problems are caused by an interference between the cells in the polarization on the ferroelectric film 106. (See JP-A-2002-203916)

### SUMMARY

According to an embodiment of the invention, there is provided a ferroelectric storage device including: a plurality of memory cells repeatedly arranged in a predetermined direction, each memory cell including a ferroelectric film divided for each memory cell; and a word line formed on the ferroelectric film and shared by the plurality of memory cells.

According to another embodiment of the invention, there is provided a ferroelectric storage device including; a plurality of memory cells repeatedly arranged in a predetermined direction, each memory cell including a ferroelectric film divided for each memory cell and a paraelectric film; and a word line formed on at least one of the ferroelectric film and the paraelectric film and shared by the plurality of memory cells.

According to still another embodiment of the present invention there is provided a method of manufacturing a ferroelectric storage device including: forming on a silicon substrate an element separation region separating a plurality of memory cells from each other; depositing on the silicon substrate a ferroelectric film after the element separation region is formed; removing the ferroelectric film deposited on the element separation region so that the ferroelectric film can be divided for each memory cell; and forming a word line on the silicon substrate after the ferroelectric film is divide for each memory cell.

### BRIEF DESCRIPTION OF THE DRAWINGS

In the accompanying drawings;

FIGS. 1A, 1B are exemplary structural views showing a memory cell portion of the ferroelectric storage device according to an embodiment 1;

FIG. 2 is an exemplary sectional view taken on line B-B of the memory cell 11 of the ferroelectric storage device according to the embodiment 1;

FIG. 3 is an exemplary image view showing a state in which data is stored in the memory cell of the ferroelectric storage device according to the embodiment 1;

FIGS. 4A, 4B, 4C are exemplary sectional views showing a method of manufacturing a ferroelectric storage device according to the embodiment 1;

FIG. 5 is an exemplary sectional view showing another method of manufacturing a ferroelectric storage device according to the embodiment 1;

FIGS. 6A, 6B are exemplary structural views showing a memory cell portion of the ferroelectric storage device according to an embodiment 2;

FIGS. 7A, 7B are exemplary structural views showing a memory cell portion of the ferroelectric storage device according to an embodiment 3; and

FIGS. 8A, 8B are exemplary structural views showing a memory cell portion according to a related-art ferroelectric storage device.

### DESCRIPTION OF THE EMBODIMENTS

Referring to the drawings, embodiments will be explained as follows.

### Embodiment 1

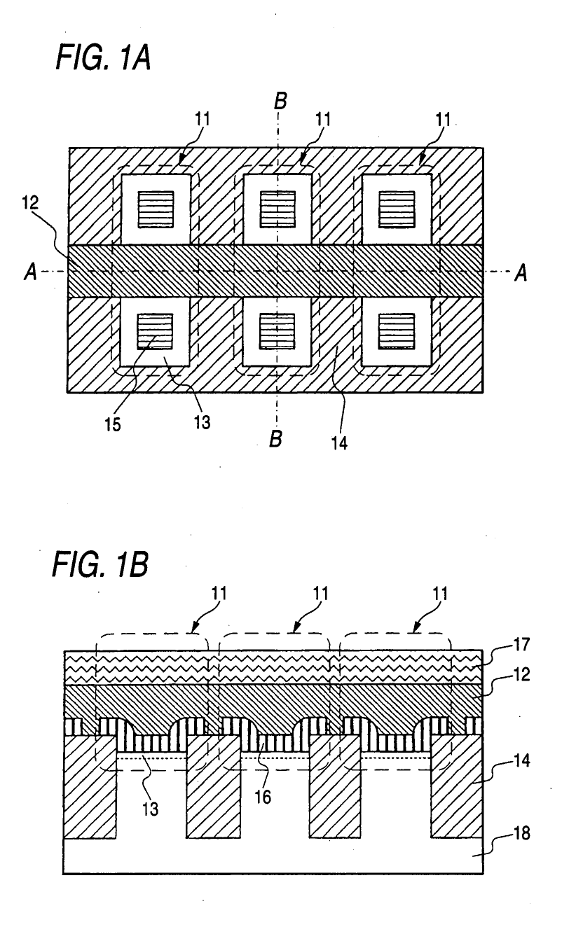

FIGS. 1A, 1B are exemplary structural views showing a memory cell portion of the ferroelectric storage device of an embodiment 1. FIG. 1A is a plan view mainly showing three memory cells 11 having a word line 12 in common. FIG. 1B is a sectional view taken on line A-A in FIG. 1A in the direction of the word line 12. In this connection, in the plan view of FIG. 1A, in order to simplify the explanation, an upper layer insulating film 17 is omitted.

As shown in the plan view of FIG. 1A, the memory cell portion of the ferroelectric storage device is configured by a plurality of memory cells 11 including the word line 12 in common are repeatedly arranged in the direction of the word line 12 (a lateral direction in FIG. 1A) while an element separation region 14 is being interposed between the memory cells 11. As shown in the sectional view of FIG. 1B, below the word line 12, a ferroelectric film 16 serving as a gate insulating film is formed to separate memory cells 11 with each other.

An element separation region 14 is formed on a main surface layer portion of a silicon substrate 18 (referred to as a board 18 hereinafter) so that an active region 13 of a field effect transistor can be separated. The active region partly configures the memory cell 11.

The ferroelectric film 16 is formed on the active region 13 and divided on the element separation region 14 for each memory cell 11.

The word line 12 is a gate electrode of the field effect transistor and formed on the ferroelectric film 16. The gate electrode partly configures the memory cell. On the word line 12, a layer insulating film 17 is formed to cover the entire memory cell portion.

Concerning the field effect transistor configured by the memory cell 11, the active region 13 (the source electrode and the drain electrode) is arranged while the word line 12 (the gate electrode) is being interposed between the field effect transistor and the active region 13, and the field effect transistor serves as a data storage element utilizing the polarization of the ferroelectric film 16.

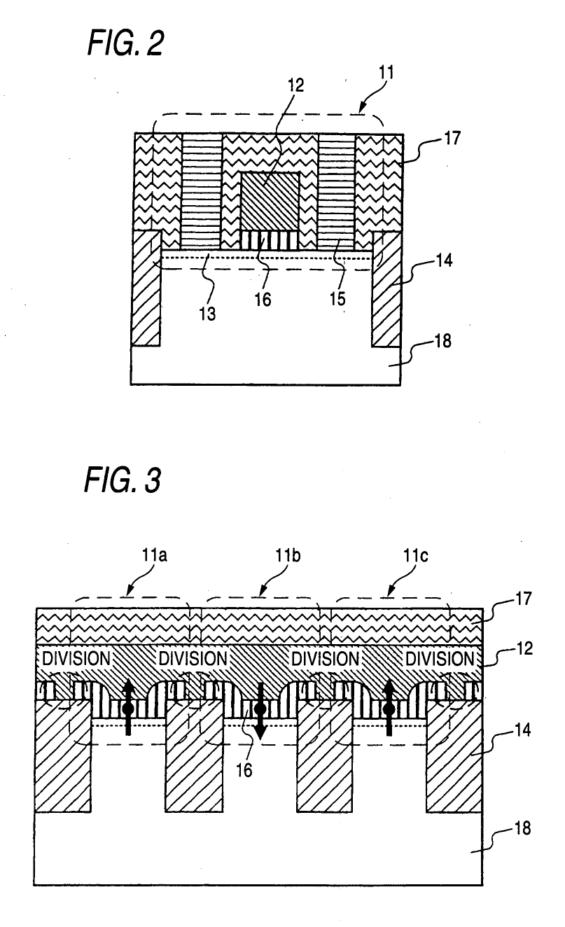

FIG. 2 is an exemplary sectional view taken on line B-B of the memory cell 11 of the ferroelectric storage device of the embodiment 1. As shown in FIG. 2, the ferroelectric film 16 is substantially the same as the word line 12 in width. In the active regions 13 (the drain electrode and the source electrode) arranged on both sides of the word line 12 and the ferroelectric film 16, contacts 15 serving as electrical connection are respectively formed penetrating the insulating film 17.

Next, the memory cell 11 serving as a data storage element will be explained below. FIG. 3 is an exemplary image view showing a state in which data is stored in the memory cell 11 of the ferroelectric storage device of the embodiment 1.

An example is shown in which data “0” is stored in the memory cells 11a and 11c and data “1” is stored in the memory cell 11b.

The memory cell 11 stores data “0” or “1” depending upon a direction of the polarization of the ferroelectric film 16. For example, in the case shown in FIG. 3, the polarization represented by a direction (shown by a downward arrow in FIG. 3) from the word line 12 to the board 18 stores data “1”, and the polarization represented by a direction (shown by an upward arrow in FIG. 3) from the board 18 to the word 12 stores data “0”.

The memory cell 11 serves as a data storage element, since an ON-resistance value of the field effect transistor is changed according to the direction of the polarization on the ferroelectric film 16 serving as the gate insulating film.

As shown in FIG. 3, in the case of the memory cell 11 composed as described above, the ferroelectric film 16 is divided on the element separation region 14. When the ferroelectric film 16 is divided as described above and a space formed between the divided ferroelectric films 16 is filled with the word line 12, an electric field made by the polarization of the memory cell 11 is not substantially transmitted to the adjoining memory cell 11. Accordingly, it is possible to reduce an influence given to the polarization of the ferroelectric film of the adjoining memory cell 11 by the polarization of the ferroelectric film 16 in the memory cell 11.

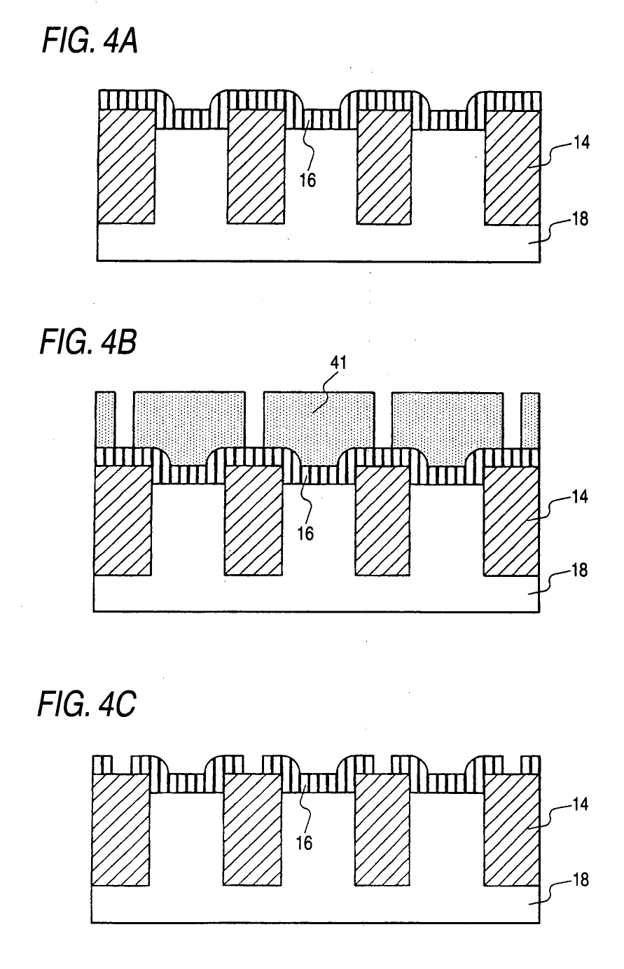

Next, a method of manufacturing a ferroelectric storage device as describe above will be explained below. FIGS. 4A, 4B, 4C are exemplary sectional views showing a method of manufacturing a ferroelectric storage device of the embodiment 1. FIGS. 4A, 4B, 4C mainly show a portion relating to a formation of the ferroelectric film 16.

The method of manufacturing a ferroelectric storage device of the embodiment 1 includes: a formation of an element separation region 14; accumulation of the ferroelectric film 16; a division of a ferroelectric film 16; and a formation of the word line 12.

When the element separation region 14 is formed, the element separation region 14 is formed on a primary surface portion of the board 18 in order to separate the memory cells 11 serving as a field effect transistor from each other.

When the ferroelectric film 16 is deposited, as shown in FIG. 4A, the ferroelectric film 16 is deposited on an entire surface of the board 18 and annealed for crystallization.

When the ferroelectric film 16 is divided, as shown in FIG. 4B, the photo resist 41 is partly removed by Photo-lithography. A portion where the ferroelectric film 16 is going to be removed is defined as a mask material pattern of the photo-resist 41. Then, as shown in FIG. 4C, while the mask material pattern is being used as a mask, the ferroelectric film 16 is etched by RIE (Reactive Ion Etching), and a portion on the element separation region 14 is removed. Accordingly, the ferroelectric film 16 is divided.

When the word line 12 is formed, conductive material formed into the gate electrode is deposited on the divided ferroelectric film 16. The thus accumulated conductive material and the divided ferroelectric film 16 are processed by a common method. In this way, the field effect transistor including the word line 12 and the memory cell 11 is formed.

After that, a layer insulating film 17 such as a silicon oxide film is deposited on the memory cell 11 and flattened. Further, by a well-known method, a contact 15 connected to the source region and the drain region of the field effect transistor and a wiring layer connected to the contact 15 are formed.

According to the embodiment 1 described above, since the ferroelectric films 16 are separated from each other for each memory cell 11, one polarization and the other polarization do not affect each other. Therefore, an amount of the bit line signal sent from the memory cell 11 is not changed by the data of the adjoining memory cell 11. Accordingly, it is possible to suppress a fluctuation of the amount of the bit line signal, and the data can be stably read out irrespective of the data of the adjoining memory cell 11.

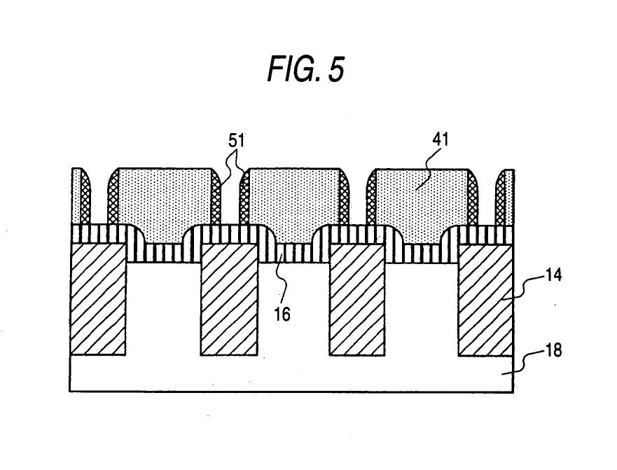

In Embodiment 1 described above, in order to make it easy to explain the structure, the photo-resist 41 is used for the mask material to divide the ferroelectric film 16. However, the present invention is not limited to the above specific embodiment. For example, in the case where a space formed between the mask materials is too small and it is difficult to form the space by PEP, the following method may be adopted. As shown in FIG. 5, a spacer 51 is formed on a side wall of the mask material, the width of which is somewhat wide, by the technique of leaving the side wall, and finally a small space is formed between the masks.

The mask material may be made in such a manner that a pattern of the photo-resist 41 is transferred onto another material, for example, a silicon oxide film.

In Embodiment 1 described above, the ferroelectric film 16 is directly deposited on a silicon surface of the active region 13 after the element separation region 14 is formed. However, the present invention is not limited to the above specific embodiment. For example, in order to reduce a possibility that the ferroelectric film 16 reacts with the silicon surface of an under-layer, a buffer layer may be deposited before the ferroelectric film 16 is deposited.

### Embodiment 2

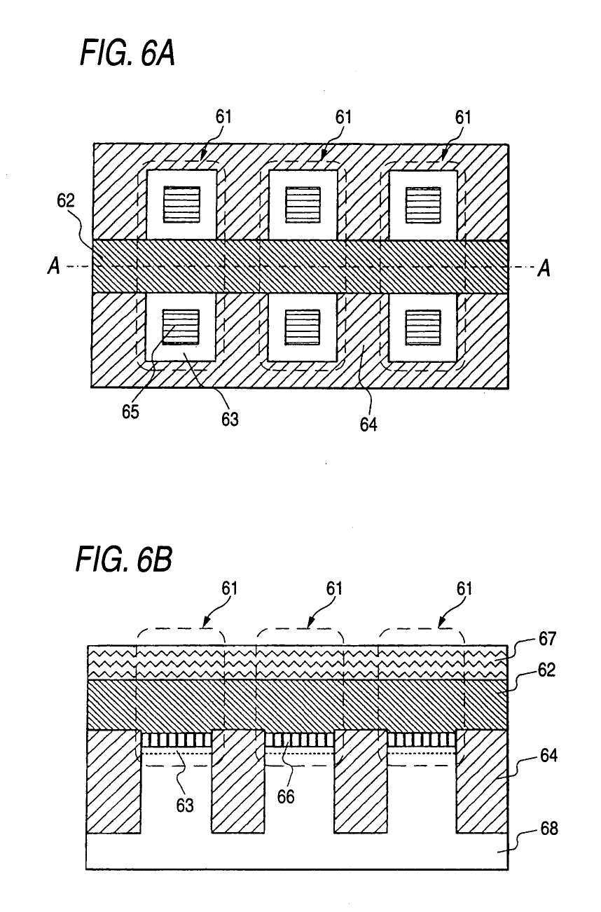

FIGS. 6A, 6B are exemplary structural views showing a memory cell portion of the ferroelectric storage device of Embodiment 2 of the present invention. FIG. 6A is a plan view mainly showing three memory cells 61 having a word line 62 in common. FIG. 6B is a sectional view taken on line A-A in FIG. 6A in the direction of the word line 62. In the plan view of FIG. 6A, in order to simplify the explanation, an upper layer insulating film 67 is omitted.

As shown in the plan view of FIG. 6A, the memory cell portion of the ferroelectric storage device according to an embodiment 2 is configured by a plurality of memory cells 61 having the word line 62 in common are repeatedly arranged in the direction of the word line 62 (the lateral direction in FIG. 6A) while an element separation region 64 is interposed between the memory cells 61. As shown in the sectional view of FIG. 6B, below the word line 62, a ferroelectric film 66 serving as a gate insulating film is formed to divide the memory cells 61 with each other.

A structure and function of each portion except for the ferroelectric film 66 are the same as those of the embodiment 1. Therefore, the detailed explanation is omitted here.

A different point of Embodiment 1 from Embodiment 2 is that the ferroelectric film 66 is formed only on the. active region 63 of the field effect transistor as shown in FIG. 6B. The memory cell 61 serves as the field effect transistor. That is, the ferroelectric film 66 is formed to be embedded on the active region 63 surrounded by the element separation region 64. That is, the ferroelectric film 66 is not formed on the element separation region 64.

In order to make the ferroelectric film 66 as described above, for example, in the manufacturing method of Embodiment 1, instead of FIGS. 4B and 4C, the following processes may be added. CMP (Chemical Mechanical Polishing) for selectively etching the ferroelectric film 66 is performed, and the ferroelectric film 66 provided in the element separation region 64 is removed entirely.

According to Embodiment 2 described above, since the ferroelectric film 66 is separated for each memory cell 61, not only the same effect as that of Embodiment 1 can be provided but also it is possible to evade a difficulty caused in a manufacturing process of manufacturing the fine ferroelectric storage device.

That is, according to Embodiment 2 described above, the ferroelectric film 66 is self-organized in the element separation region 64 by CMP. Therefore, it is unnecessary to work the ferroelectric film 66 on the element separation region 64 by PEP, and it is possible to evade the occurrence of a problem caused when a ferroelectric storage device of fine structure is manufactured.

In Embodiment 2 described above, the ferroelectric film 66 is directly deposited on a silicon surface of the active region 63 after the element separation region 64 has been formed. However, the present invention is not limited to the above specific embodiment. For example, in order to reduce a possibility that the ferroelectric film 66 reacts with the silicon surface of an under-layer, a buffer layer may be accumulated before the ferroelectric film 66 is accumulated.

### Embodiment 3

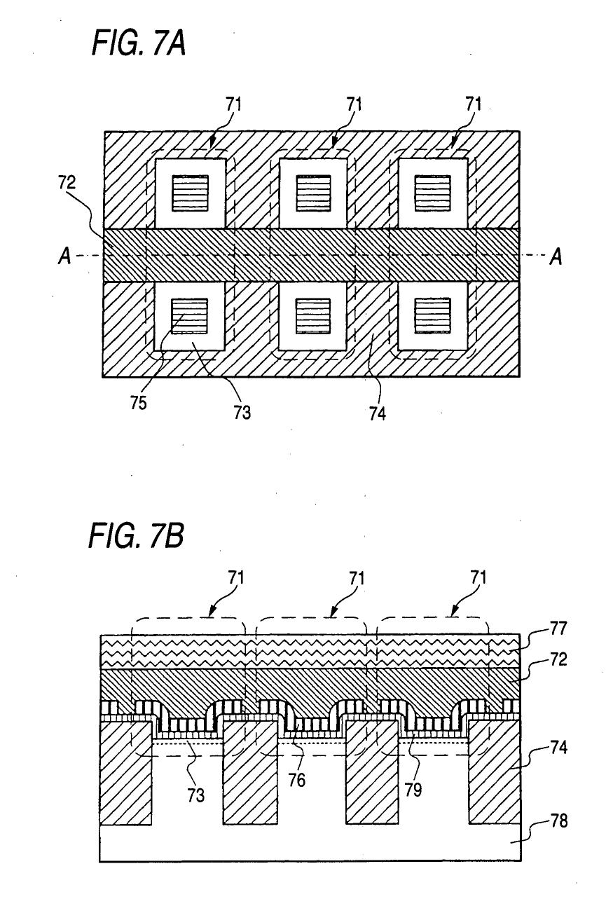

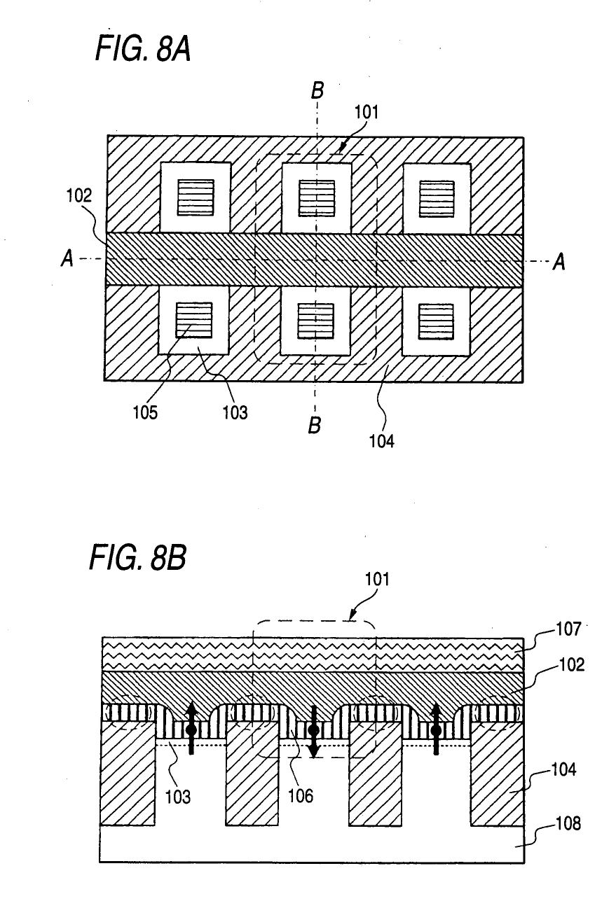

FIGS. 7A, 7B are structural views showing a memory cell portion of the ferroelectric storage device of according to an embodiment 3. FIG. 7A is a plan view mainly showing three memory cells 71 having a word line 72 in common. FIG. 7B is a sectional view taken on line A-A in FIG. 7A in the direction of the word line 72. In this connection, in the plan view of FIG. 7A, in order to simplify the explanation, an upper layer insulating film 77 is omitted.

As shown in the plan view of FIG. 7A, the memory cell portion of the ferroelectric storage device is configured by a plurality of memory cells 71 having the word line 72 in common which are repeatedly arranged in the direction of the word line 72 (the lateral direction in FIG. 7A) while an element separation region 74 is being interposed between the memory cells 71.

As shown in the sectional view of FIG. 7B, below the word line 72, the ferroelectric film 76 and the paraelectric film 79 are laminated as a gate insulating film. That is, the paraelectric film 79 is formed in the active region 73 of the field effect transistor composing the memory cell 71 and in the element separation region 74. Therefore, the ferroelectric film 76 is formed on the paraelectric film 79 to divide the memory cells 71 with each other.

A structure and function of each portion except for the paraelectric film 79 are the same as those of Embodiment 1. Therefore, the detailed explanation is omitted here.

A different point of the embodiment 3 from Embodiment 1 is described as follows. As described before, the paraelectric film 79 is provided as a buffer film below the ferroelectric film 76, and only the ferroelectric film 76 is divided on the element separation region 74, and the paraelectric film 79 is left as it is.

Even when the thin paraelectric film 79 is left on the element separation region 74, the same effect as that of Embodiment 1 can be sufficiently provided. Since the thin paraelectric film 79 is left on the element separation region 74, when the ferroelectric film 76 etched so as to form a space, the paraelectric film 79 can be used as an etching stopper.

Concerning the method of manufacturing a ferroelectric storage device having the above structure, for example, in the manufacturing method of Embodiment 1, before the ferroelectric film 76 is accumulated in FIG. 4A, a paraelectric film 79 may be deposited with a predetermined thickness on the entire surface of the memory cell portion.

According to Embodiment 3 described above, since the ferroelectric film 76 is separated for each memory cell 71, it is possible to provide the same effect as that of Embodiment 1. Further since the paraelectric film 79 can be utilized as an etching stopper, it is possible to enhance the etching control property of the ferroelectric film 76 and the manufacturing process can be easily executed.

According to the above-described embodiments, a ferroelectric storage device in which an interference of an amount of the polarization of the ferroelectric film between the memory cells adjacent to each other is suppressed so that data can be stably read out.

According to the above-described embodiments, the ferroelectric film is separated for each memory cell. Therefore, data can be stably read out irrespective of the data of the adjoining memory cell.

What is claimed is:

1. A ferrqelectric storage device comprising:
a plurality of memory cells repeatedly arranged in a predetermined direction, each memory cell comprising a ferroelectric film divided for each memory cell; and
a word line formed on the ferroelectric film and shared by the plurality of memory cells.

2. A ferroelectric storage device according to claim 1, wherein each memory cell comprises an active region and serves as a data storage element by controlling in accordance with a direction of polarization of the ferroelectric film a current that flows in the active region.

3. A ferroelectric storage device according to claim 2, wherein an element separation region separates each memory cell and divides the ferroelectric film in each memory cell, and
wherein the ferroelectric film is formed on the active region.

4. A ferroelectric storage device according to claim 2, comprising;
an insulating film formed on a part of the word line on which the ferroelectric film is formed, and the insulating film covering the plurality of memory cells.

5. A ferroelectric storage device according to claim 4, wherein the insulating film is substantially the same as the word line in width, and
wherein a contact serving as electrical connection is formed penetrating the insulating film on a part of the active region that is provided at both sides of the word line and both sides of the ferroelectric film.

6. A ferroelectric storage device according to claim 2, wherein an element separation region separates each memory cell, and
wherein the ferroelectric film is formed only on a part of the active region where the element separation region surrounds.

7. A ferroelectric storage device comprising;
a plurality of memory cells repeatedly arranged in a predetermined direction, each memory cell comprising a ferroelectric film divided for each memory cell and a paraelectric film; and
a word line formed on at least one of the ferroelectric film and the paraelectric film and shared by the plurality of memory cells.

8. A ferroelectric storage device according to claim 7, wherein the plurality of memory cells comprise an active region,
wherein the ferroelectric film is formed on the paraelectric film, and
wherein the plurality of memory cells serve as an data storage element by controlling in accordance with a direction of the polarization of the ferroelectric film a current that flows in the active region.

9. A ferroelectric storage device according to claim 8, comprising;
an element separation region separating each memory cell, wherein the ferroelectric film is formed on the active region, and
wherein the ferroelectric film is divided for each memory cell on the element separation region.

10. A ferroelectric storage device according to claim 9, comprising;
an insulating film formed on a part of the word line on which the ferroelectric film is disposed and being substantially the same as the word line in width, the insulating film covering the plurality of memory cells, and
wherein a contact serving as electrical connection is formed penetrating the insulating film on a part of the active region that is provided at both sides of the word line and both sides of the ferroelectric film.

11. A ferroelectric storage device according to claim 1, wherein the ferroelectric film is divided on an element separation region for separating the plurality of memory cells serving as a field effect transistor from each other.

12. A ferroelectric storage device according to claim 7, wherein the ferroelectric film is divided on an element separation region-for separating the plurality of memory cells serving as a field effect transistor from each other.

13. A ferroelectric storage device according to claim 1, wherein the ferroelectric film is formed only on an active region of the plurality of memory cells serving as a field effect transistor.

14. A method of manufacturing a ferroelectric storage device comprising:
forming on a silicon substrate an element separation region separating a plurality of memory cells from each other;
depositing on the silicon substrate a ferroelectric film after the element separation region is formed;
removing the ferroelectric film deposited on the element separation region so that the ferroelectric film can be divided for each memory cell; and
forming a word line on the silicon substrate after the ferroelectric film is divide for each memory cell.

15. A method of manufacturing a ferroelectric storage device according to claim 14, comprising;
forming on the silicon substrate an active region capable of controlling, by a direction of the polarization of the ferroelectric film, a current that flows in the active region;
forming the insulating film of which a width is substantially as same as a width of the word line, the insulating film covering the plurality of memory cells; and
forming on both sides of the word line and both sides of the ferroelectric film a contact serving as electrical connection and penetrating the insulating film.

16. A method of manufacturing a ferroelectric storage device according to claim 14, comprising;
forming the ferroelectric film on only a part of the active region surrounded by the element separation region.
